(19) United States
(12) Patent Application Publication
(10) Pub. No.: US 2026/0324510 A1
(43) Pub. Date: Oct. 15, 2026

(54) SEMICONDUCTOR PACKAGES WITH SIGNAL INTEGRATION AND THE METHODS OF MANUFACTURING THE SAME

(71) Applicant: Taiwan Semiconductor Manufacturing Co., Ltd., Hsinchu (TW)

(72) Inventors: Chung-Ming Weng, Hsinchu (TW); An-Jhih Su, Taoyuan City (TW); Tzuan-Horng Liu, Longtan Township (TW)

(21) Appl. No.: 19/712,368

(22) Filed: Jun. 18, 2026

Related U.S. Application Data
(63) Continuation of application No. 18/591,758, filed on Feb. 29, 2024.
(60) Provisional application No. 63/598,577, filed on Nov. 14, 2023.

(51) Int. Cl. H10W 90/00; H10W 20/20; H10W 42/00; H10W 72/00; H10W 72/20; H10W 74/00; H10W 74/15

(52) U.S. Cl. CPC H10W 90/00; H10W 20/20; H10W 42/00; H10W 72/072; H10W 72/241; H10W 72/877; H10W 74/00; H10W 74/15; H10W 90/722; H10W 90/724; H10W 90/734

(57) ABSTRACT

A method includes forming a die, which further includes forming a first through-via and a second through-via extending from a front side of a semiconductor substrate into the semiconductor substrate. The first through-via and the second through-via are connected to a first integrated circuit device and a second integrated circuit device, respectively, in the die. A backside grinding process is performed to reveal the first through-via and the second through-via. A backside redistribution line is formed to physically join to both of the first through-via and the second through-via.

### PRIORITY CLAIM AND CROSS-REFERENCE

This application is a continuation of U.S. patent application Ser. No. 18/591,758, filed Feb. 29, 2024 and entitled “Semiconductor Packages With Signal Integration and the Methods of Manufacturing the Same,” which claims the benefit of U.S. Provisional Application No. 63/598,577, filed on Nov. 14, 2023, and entitled “Semiconductor Package and Method of Manufacturing the Same,” which applications are hereby incorporated herein by reference.

### BACKGROUND

The packages of integrated circuits are becoming increasing complex, with more device dies packaged in the same package to achieve more functions. For example, a package structure has been developed to include a plurality of device dies such as processors and memory cubes in the same package. The package structure can include device dies formed using different technologies and have different functions bonded to the same device die, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate the cross-sectional views of intermediate stages in the formation of a package in accordance with some embodiments.

FIG. 10 illustrates an amplified view of a portion of a package in accordance with some embodiments.

FIGS. 11 and 12 illustrate the bottom views of some portions of the package in accordance with some embodiments.

FIGS. 13A, 13B, 13C through 22A, 22B, and 22C illustrate the views of some portions of packages in accordance with some embodiments.

FIGS. 23A and 23B through 26A and 26B illustrate the views of some portions of the package in accordance with some embodiments.

FIGS. 27A, 27B, 28A, 28B, 29A and 29B illustrate the views of some portions of dummy bumps in packages in accordance with some embodiments.

FIG. 30 illustrates a portion of the package in accordance with some embodiments.

FIGS. 31A through 31I illustrate the top views of dummy bumps in accordance with some embodiments.

FIGS. 32-34 illustrate some applications of the packages in accordance with some embodiments.

FIG. 35 illustrates a process flow for forming a package in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package and the method of forming the same are provided. In accordance with some embodiments of the present disclosure, a package includes a device die comprising Through-silicon vias (TSVs), which penetrate through a semiconductor substrate. The device die is referred to as a TSV die hereinafter. Backside Redistribution lines (RDLs) are formed on the backside of the semiconductor substrate. The backside RDLs may be used for integrating the signals from different TSVs, and hence a backside RDL may be electrically connected to multiple TSVs, which are connected to different circuits. Accordingly, the signals from the multiple TSVs may be connected to a same metal bump in the device die, which is used for bonding. The backside RDLs may also be connected to an overlying RDL (also referred to as a middle RDL), which may also integrate signals that are connected to different metal bumps. By integrating signals, fewer metal bumps may be needed for bonding, and fewer middle RDLs may be needed.

Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

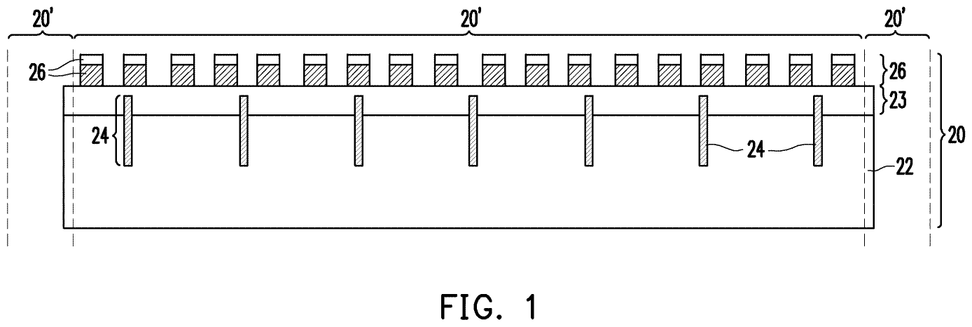

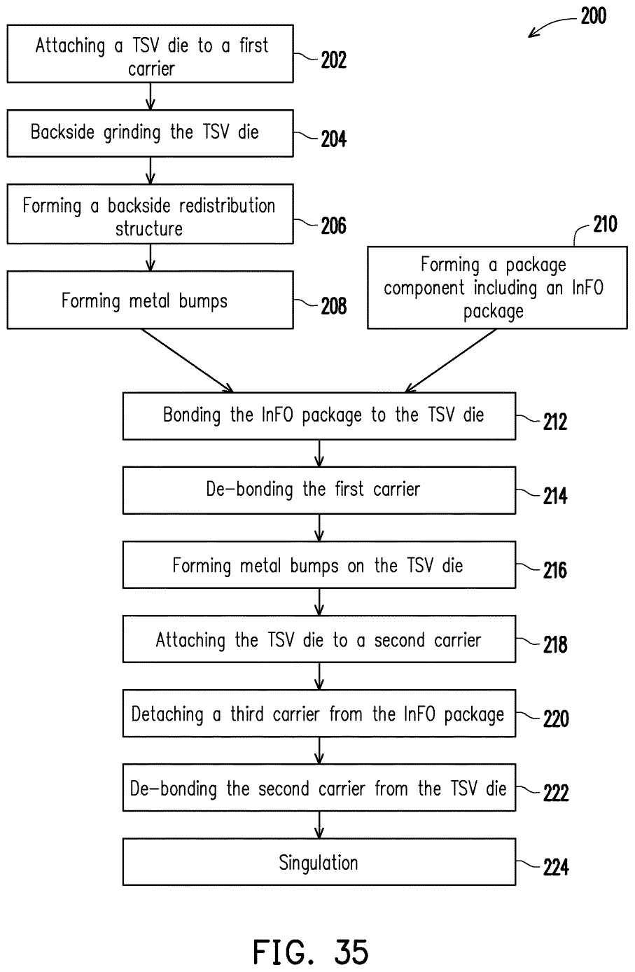

FIGS. 1 through 9 illustrate the cross-sectional views of intermediate stages in the formation of a package in accordance with some embodiments of the present disclosure. The corresponding processes are also reflected schematically in the process flow shown in FIG. 35.

FIG. 1 illustrates a wafer 20 in accordance with some embodiments. Wafer 20 includes identical device dies 20′ therein. Furthermore, wafer 20 includes semiconductor substrate 22, which may be or may include silicon, silicon germanium, carbon doped silicon, or the like. Integrated circuit devices (not shown, refer to integrated circuits 94′ and 94″ in FIG. 10) such as transistors, capacitors, inductors, resistors, and the like, may be formed in wafer 20, and may be in or over semiconductor substrate 22.

Through-vias (also referred to as through-silicon vias (TSVs) or through-substrate vias (also TSVs)) 24 are formed extending into semiconductor substrate 22. The TSVs 24 extend to an intermediate level between a top surface and a bottom surface of the semiconductor substrate 22. Each of the TSVs 24 is encircled by, and is separated from semiconductor substrate 22 by, a dielectric isolation layer (not shown). Device dies 20′ are thus alternatively referred to as TSV dies 20′.

An interconnect structure 23 is formed over semiconductor substrate 22. The interconnect structure 23 includes a plurality of dielectric layers, which may include low-k dielectric layers, and metal lines and vias in the dielectric layers. The metal lines and vias electrically interconnect the integrated circuit devices as function circuits. The TSVs 24 may extend into any level of the interconnect structure 23. Metal bumps 26 are formed over the interconnect structure 23, and are electrically connected to the metal lines and vias in the interconnect structure, the integrated circuits in wafer 20, and TSVs 24.

In accordance with some embodiments, metal bumps 26 are formed on the top surface of wafer 20. Metal bumps 26 may be formed through plating. Metal bumps 26 may include copper bumps, and may or may not include nickel bumps, solder bumps, and/or the like.

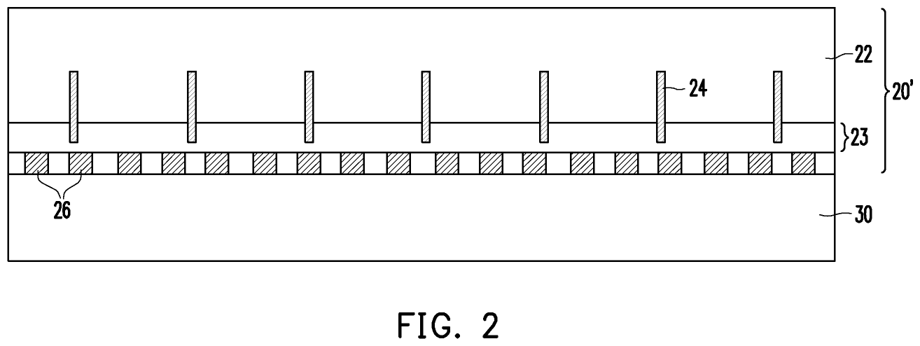

Referring to FIG. 2, wafer 20 is attached to carrier 30, with the front side (such as a dielectric bond film (not shown)) of wafer 20 facing and attached to carrier 30. The respective process is illustrated as process 202 in the process flow 200 as shown in FIG. 35. In accordance with some embodiments, carrier 30 includes a bulk semiconductor carrier such as a silicon carrier, and a bond layer on the bulk semiconductor carrier. The bond layer may be formed of a silicon-containing dielectric material selected from SiO, SiC, SiN, SiON, SiOC, SiCN, SiOCN, or the like, or combinations thereof. Wafer 20 may be attached to carrier 30 through fusion bonding, with the surface bond layer of wafer 20 being bonded to the bond layer in carrier 30 in accordance with some embodiments.

In accordance with alternative embodiments, carrier 30 includes a transparent substrate such as a glass substrate. An adhesive such as a Light-To-Heat-Conversion (LTHC) material (not shown) is applied on carrier 30, and adheres wafer 20 to carrier 30. The LTHC material is capable of being decomposed under the heat of light (such as a laser beam).

In a subsequent process, a backside grinding process is performed to thin semiconductor substrate 22. The backside grinding process is performed until TSVs 24 are revealed. The respective process is illustrated as process 204 in the process flow 200 as shown in FIG. 35.

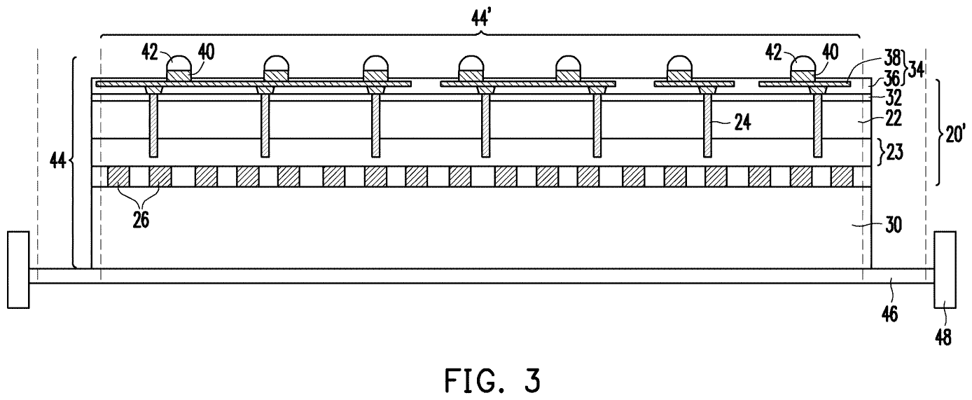

Next, as shown in FIG. 3, a backside redistribution structure 34 is formed on the backside of wafer 20. The respective process is illustrated as process 206 in the process flow 200 as shown in FIG. 35. In accordance with some embodiments, semiconductor substrate 22 is recessed through an etch-back process. Accordingly, the top portions of TSVs 24 protrude higher than the top surface (the back surface) of semiconductor substrate 22. The space higher than the back surface of semiconductor substrate 22 and lower than the top ends of TSVs 24 are referred to as recesses.

Next, the recesses are filled with dielectric isolation layer 32. Dielectric isolation layer 32 is formed of or comprises an inorganic dielectric material such as silicon nitride, silicon oxynitride, silicon oxycarbonitride, silicon oxide, silicon carbide, silicon oxycarbide, or the like, or combinations thereof. The formation process may comprise a conformal or non-conformal deposition process, which may be performed using Atomic Layer Deposition (ALD), Chemical Vapor Deposition (CVD), Plasma-Enhanced Chemical Vapor Deposition (PECVD), or the like. After the deposition, a planarization process is performed to remove the portions of dielectric isolation layer 32 higher than the top ends of TSVs 24. Accordingly, the top surface of dielectric isolation layer 32 is coplanar with the top ends of TSVs 24.

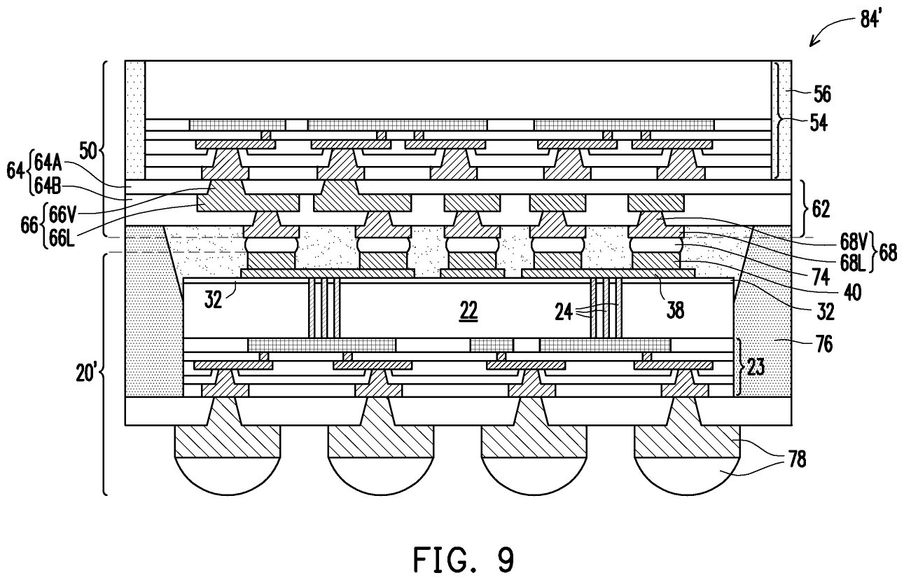

Next, as shown in FIG. 3, backside redistribution structure 34 is formed, which includes RDLs 38. There may be, or may not be, dielectric layer(s) 36, depending on how many layers of RDLs 38 are formed. It is appreciated that the backside redistribution structure 34 is shown schematically in FIG. 3, while the details may be found in subsequent FIGS. 9 and 10 that show amplified portions. The formation of backside redistribution structure 34 may also include forming metal bumps 40, which may be copper bumps in accordance with some embodiments. The respective process is illustrated as process 208 in the process flow 200 as shown in FIG. 35. Solder regions 42 may be formed on metal bumps 40.

In accordance with some embodiments, the formation of dielectric layer(s) 36 (if any), RDLs 38, metal bumps 40, and solders 42 may include depositing a dielectric layer (if any), patterning the dielectric layer to reveal the underlying conductive features such as TSVs 24 or RDLs 38, and forming a metal seed layer. A plating mask such as a patterned photoresist is then formed, with some portions of the metal seed layer being revealed through openings in the plating mask. Conductive features such as RDLs 38, metal bumps 40, and/or solders 42 are then formed in the openings of the plating mask through plating. The plating mask is then removed, exposing some portions of the metal seed layer. The exposed portions of the metal seed layer are then etched. The dielectric layers 36 (if any) may comprise polyimide, Polybenzoxazole (PBO), or the like.

Wafer 20 and carrier 30 are collectively referred to as composite wafer 44 hereinafter. Next, as shown in FIG. 3, composite wafer 40 is placed on dicing tape 46, which is fixed on frame 48. A singulation process is then preformed to saw composite wafer 44 into packages 44′, each including one of TSV dies 20′ therein.

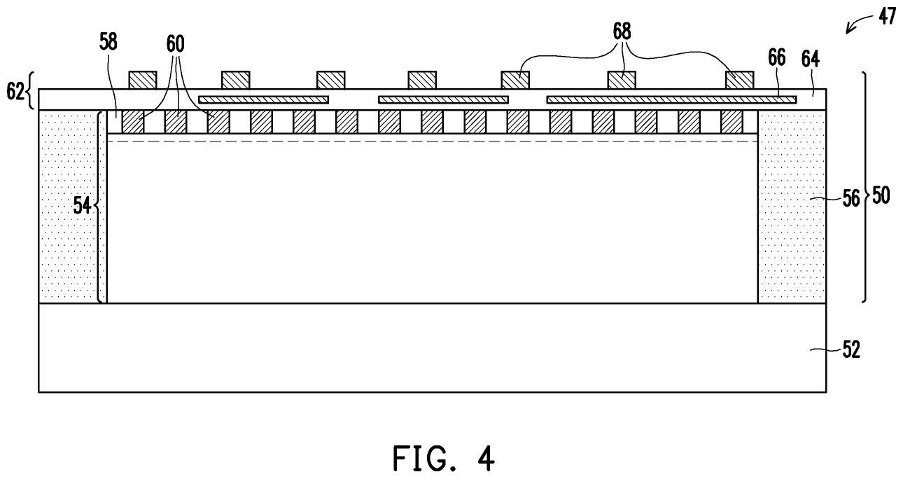

FIG. 4 illustrates the formation of package component 47, which is to be bonded to the structure shown in FIG. 3. The respective process is illustrated as process 210 in the process flow 200 as shown in FIG. 35. Referring to FIG. 4, InFO package 50 is attached to carrier 52. Carrier 52 may be formed of the materials and structures selected from the same group of candidate materials and structures of carrier 30 (FIG. 2), and may include a glass substrate, a silicon substrate, or the like. In accordance with some embodiments, InFO package 50 may include a device die 54 (or a package including a plurality of device dies), which may represent a single device die or a plurality of device dies bonded to form a package. Although one device die 54 is illustrated, there may be a plurality of device dies 54 placed over carrier 52. The plurality of device dies may also form a system in accordance with some embodiments. Device die 54 may include metal bumps 58 and surface dielectric layer 60.

In accordance with some embodiments, device die 54 is encapsulated in gap-filling regions 56 (also referred to as encapsulant 56). In accordance with some embodiments, gap-filling regions 56 comprise a dielectric liner and a dielectric region on the dielectric liner. The Dielectric liner may be formed of or comprise silicon nitride, and the dielectric region may comprise silicon oxide.

Redistribution structure 62 is formed over device die 54 as a fanout structure. In accordance with some embodiments, redistribution structure 62 includes dielectric layers 64, and RDLs 66 in dielectric layers 64. The materials, structures, and formation processes of dielectric layers 64 and RDLs 66 may be essentially the same as that of dielectric layers 36 and RDLs 38 in packages 44′ (FIG. 3), and are not repeated herein. Redistribution structure 62 may further include metal bumps 68 (which may be copper bumps).

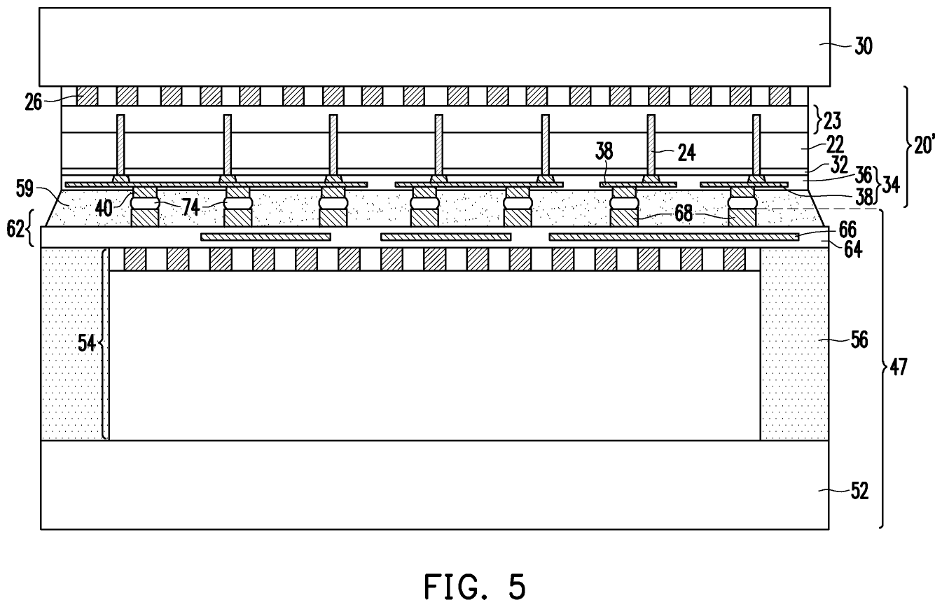

Referring to FIG. 5, the structure shown in FIGS. 3 and 4 are bonded to each other, for example, by bonding metal bumps 68 to metal bumps 40 through solder regions 74, which include solder regions 42 (FIG. 3). The respective process is illustrated as process 212 in the process flow 200 as shown in FIG. 35. Underfill 59 is formed in the gap between TSV die 20′ and InFO package 50.

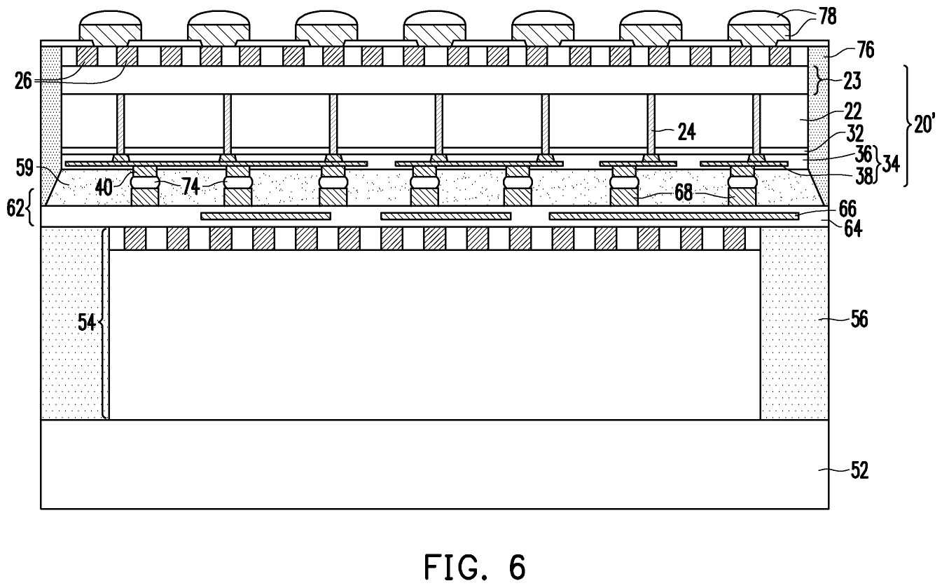

Next, carrier 30 is de-bonded from the underlying structure. The respective process is illustrated as process 214 in the process flow 200 as shown in FIG. 35. In a subsequent process, as shown in FIG. 6, an encapsulant 76, such as a molding compound, a molding underfill, or the like, is formed to encapsulating TSV die 20′ therein. The encapsulant 76 is then planarized, for example, through CMP or mechanical grinding, so that the metal bumps 26 are exposed. Subsequently, metal bumps 78 (which may include copper bumps, solder region, and/or the like) are formed on metal bumps 26. The respective process is illustrated as process 216 in the process flow 200 as shown in FIG. 35. There may be, or may not be, a redistribution structure ((not shown) formed between metal bumps 26 and metal bumps 78. The redistribution structure, if formed, also includes dielectric layers and RDLs in dielectric layers.

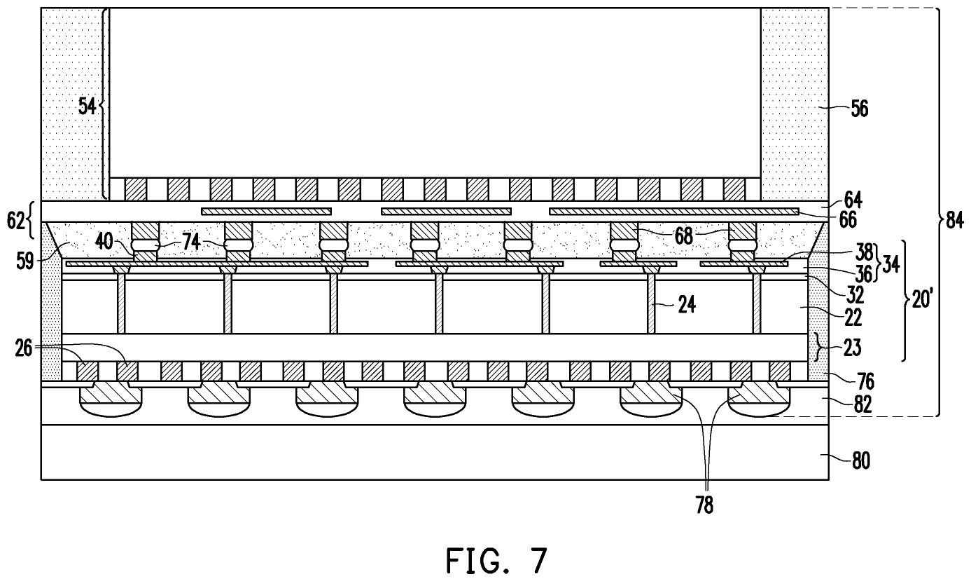

In FIG. 7, the structure in FIG. 6 is attached to carrier 80, which may be a glass carrier in accordance with some embodiments. The metal bumps 78 may be attached to adhesive 82 in accordance with some embodiments. The respective process is illustrated as process 218 in the process flow 200 as shown in FIG. 35. The carrier 52 in FIG. 6 is then detached from device die 54 and gap-filling regions 56. The respective process is illustrated as process 220 in the process flow 200 as shown in FIG. 35. The structure over carrier 80 is referred to as reconstructed wafer 84 hereinafter, which may include a plurality of identical TSV dies 20′ therein.

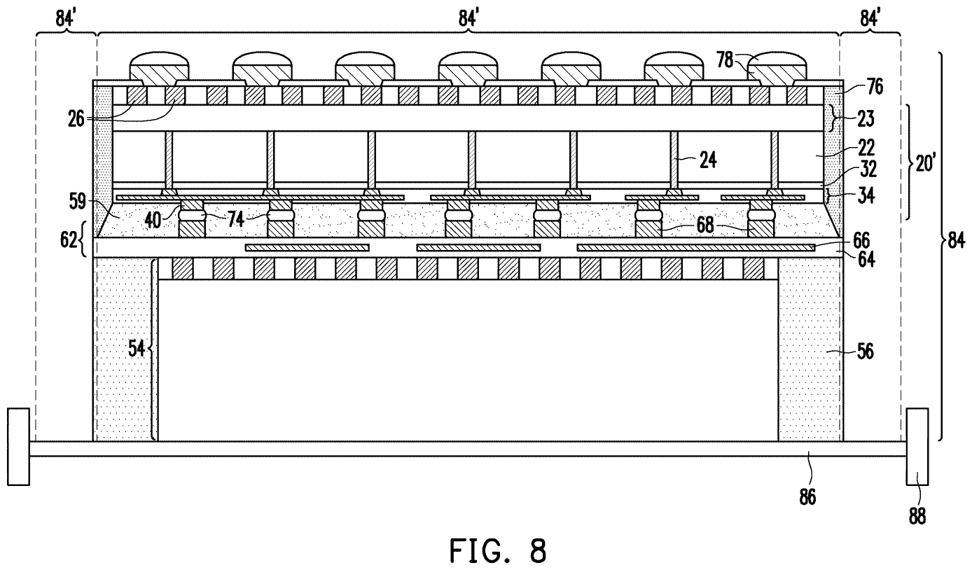

The reconstructed wafer 84 is then de-bonded from carrier 80. The respective process is illustrated as process 222 in the process flow 200 as shown in FIG. 35. FIG. 8 illustrates the attaching of reconstructed wafer 84 to dicing tape 86, which is fixed on frame 88.

Next, the reconstructed wafer 84 is singulated in a sawing process to form a plurality of identical packages 84′. The respective process is illustrated as process 224 in the process flow 200 as shown in FIG. 35. FIG. 9 illustrates a detailed structure of a package 84′ in accordance with some embodiments.

FIG. 10 illustrates an amplified portion of package 84′ in accordance with some embodiments. The features illustrated in FIG. 10 may be found from the discussion in the processes shown in FIGS. 1 through 9. It is also noted that although may be one or more dielectric layers 36 formed, with RDLs 38 being in dielectric layers 36 (also refer to in FIGS. 6 and 7). The illustrated dielectric layer 36 is marked as being dashed to indicate that dielectric layer 36 may or may not be formed, and there may be none, one, or more dielectric layers 36. In accordance with some embodiments, as shown in FIGS. 9 and 10, the redistribution structure 62, which is formed on device die 54 and gap-filling regions 56, includes dielectric layers 64 (including 64A and 64B), which may be formed of polyimide, PBO, or the like. The RDLs 66 in redistribution structure 62 include via portions 66V (including portions 66VA and 66VB) in dielectric layer 64A and line portions 66L (including portions 66LA and 66LB) in dielectric layer 64B. In accordance with some embodiments, RDLs 66 are also referred to middle RDLs (mRDLs). Redistribution structure 62 further includes metal bumps 68 (including metal bumps 68A, 68B, 68C, and 68D), which may be Under-Bump Metallurgies (UBMs) in accordance with some embodiments. UBMs 68 also include via portions 68V and line/pad portions 68L.

Further referring to FIG. 10, TSV die 20′ includes substrate 22, which may be a semiconductor substrate, and TSVs 24 penetrating through semiconductor substrate 22. TSVs 24 may include TSVs 24A′, 24B′ and 24C′, which are collectively referred to TSVs 24′. TSVs 24 may also include TSVs 24A″, 24B″ and 24C″, which are collectively referred to TSVs 24″. TSV die 20′ includes backside RDLs 38 (including RDLs 38A, 38B, and 38C), which may be in physical contact with TSVs 24. TSV die 20′ further includes metal bumps 40 (including metal bumps 40A, 40B, 40C, and 40D), which are joined to UBMs 68 through solder regions 74.

In accordance with some embodiments, TSV die 20′ includes integrated circuits 94, which includes circuits 94A′, 94B′, 94C′, 94A″, 94B″, 94C″, 94A″′, and 94B″′. Integrated circuits 94 may be formed on the front surface (the illustrated bottom surface) of semiconductor substrate 22. Metal pads 92, which include metal pads 92A′, 92B′, 92C′, 92A″, 92B″, 92C″, 92A″′, and 92B″′ are formed underlying, and in contact with TSVs 24A′, 24B′, 24C′, 24A″, 24B″, 24C″, 24A″′, and 24B″′, respectively. The metal pads 92A′, 92B′, 92C′, 92A″, 92B″, 92C″, 92A″′, and 92B″′ may be electrically connected to integrated circuits 94A′, 94B′, 94C′, 94A″, 94B″, 94C″, 94A″′, and 94B″′, respectively, through electrical paths (which includes metal lines and vias) 96A′, 96B′, 96C′, 96A″, 96B″, 96C″, 96A″′, and 96B″′, respectively.

In accordance with some embodiments, metal pads 92A′, 92B′, 92C′, 92A″, 92B″, 92C″, 92A″′, and 92B″′ are in a same metal layer of the interconnect structure 23. In accordance with alternative embodiments, metal pads 92A′, 92B′, 92C′, 92A″, 92B″, 92C″, 92A″′, and 92B″′ are in different metal layers of the interconnect structure 23 in any combination.

In accordance with some embodiments, backside RDL 38A has the function of integrating signals coming from (or conducted to) a plurality of TSVs 24′ (including TSVs 24A′, 24B′, and 24C′). For example, TSVs 24A′, 24B′, and 24C′ may be electrically connected to separate integrated circuits 94′ (including integrated circuits 94A′, 94B′, and 94C′) through signal paths 96′ (including 96A′, 96B′, and 96C′). The integrated circuits 94A′, 94B′, and 94C′ may be separate functional circuits including active devices (such as transistors) and/or passive devices (such as resistors, capacitors, or the like). Accordingly, TSVs 24A′, 24B′, and 24C′, although connected to different circuits, share the same backside RDL 38A. This is different from the conventional approaches in which each of the TSVs is joined to an individual overlying backside RDL.

In accordance with some embodiments, backside RDL 38B has the function of integrating signals coming from (or conducted to) a plurality of TSVs 24″ (including TSVs 24A″, 24B″, and 24C″). For example, TSVs 24A″, 24B″, and 24C″ are electrically connected to separate integrated circuits 94″ (including integrated circuits 94A″, 94B″, and 94C″) through signal paths 96″ (including 96A″, 96B″, and 96C″). The integrated circuits 94A″, 94B″, and 94C″ are separate functional circuits including active devices (such as transistors) and/or passive devices (such as resistors, capacitors, or the like). Accordingly, TSVs 24A″, 24B″, and 24C″, although connected to different circuits, share the same backside RDL 38B.

In accordance with some embodiments, backside RDL 38C has the function of integrating signals coming from (or conducted to) a plurality of TSVs 24″′ (including TSVs 24A″′ and 24B″′). For example, TSVs 24A″′ and 24B″′ are electrically connected to separate integrated circuits 94″′ (including integrated circuits 94A″′ and 94B″′) through signal paths 96″′ (including 96A″′ and 96B″′). The integrated circuits 94A″′ and 94B″′ are separate functional circuits including active devices (such as transistors) and/or passive devices (such as resistors, capacitors, or the like). Accordingly, TSVs 24A″′ and 24B″′, although connected to different circuits, share the same backside RDL 38C.

In FIG. 10, metal bumps 40 (including metal bumps 40A, 40B, 40C, and 40D) are formed and connected to the underlying backside RDLs 38.

In addition to integrating the underlying signals through backside RDLs 38, the signals on backside RDLs may be further integrated by mRDLs. For example, the UBMs 68A and 68B are connected to the same mRDL 66A, and hence the mRDL 66A has the function of integrating signals of underlying UBMs 68A and 68B. Similarly, mRDL 66B is connected to the two underlying UBMs 68C and 68D, and hence has the function of integrating their signals. Combining the integrating function of both of the backside RDLs 38 and the mRDLs 66 may significantly reduce the number of metal bumps on the backside of the TSV die 20′, and reduce the number of RDLs in the redistribution structure 62.

In accordance with alternative embodiments, backside RDL 38C, instead of joined to both of TSVs 24A″′ and 24B″′, may be separated into two portions, wherein region 97, instead of being a metal region, is a dielectric region. Accordingly, the signals of TSVs 24A″′ and 24B″′, instead of integrated by backside RDL 38C, is integrated by mRDL 66B.

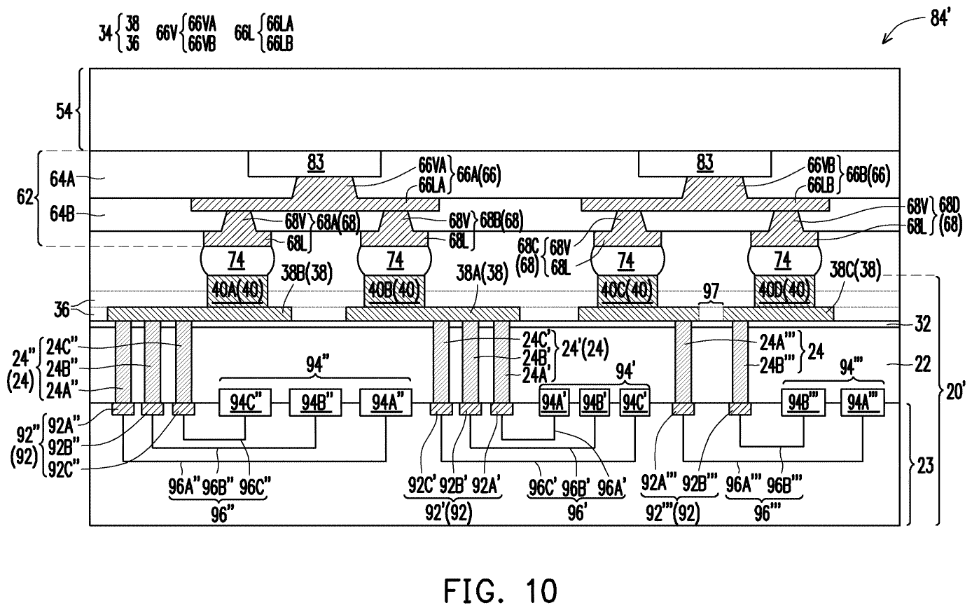

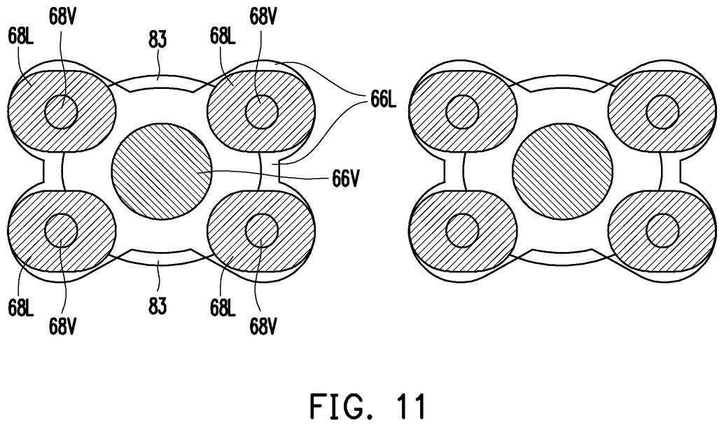

FIG. 11 illustrates a bottom view of features line portions 66L, line portions 68L (including 68-L, 68L-2, 68L-3, and 68L-4), via portions 68V, via portions 66V, and copper vias 83 in accordance with some embodiments. These features have their corresponding features shown in FIGS. 9 and 10. The plurality of trace portions 68L of UBMs 68 may be connected to different circuits 94 (FIG. 10), and their signals are integrated by the same mRDL 66 (including via portion 66V and line/pad portion 66L).

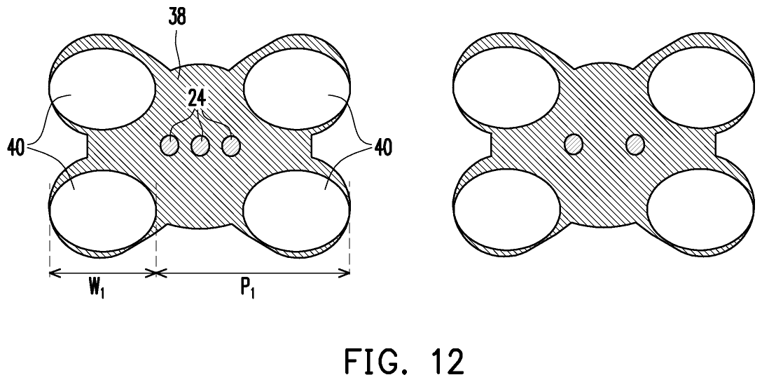

FIG. 12 illustrates a bottom view of metal bumps 40, backside RDLs 38, and TSVs 24 in accordance with some embodiments. These features have their corresponding features shown in FIGS. 9 and 10 also. The plurality of TSVs 24 may be connected to different circuits 94 (FIG. 10), and their signals are integrated by the same backside RDL 38.

In accordance with some embodiments, metal bumps 40 have pitches P1 greater than about 4 μm. The width W1 (or diameter) of metal bumps 40 may be in the range between about 2 μm and about 90 μm. The metal bumps 40 may have any applicable top-view or bottom-view shape including and not limited to circles, oblongs, ovals, hexagons, octagons, or the like.

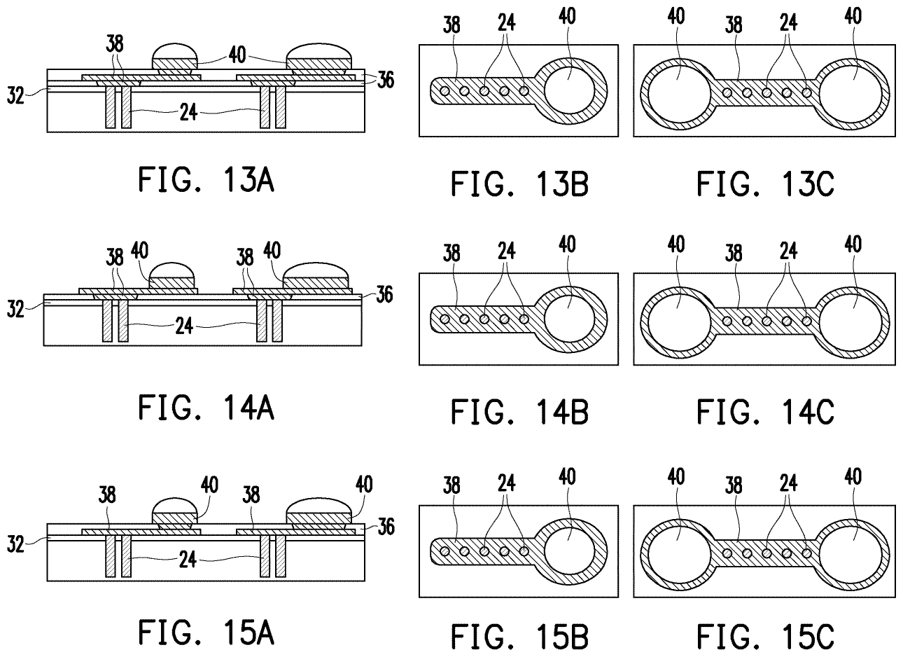

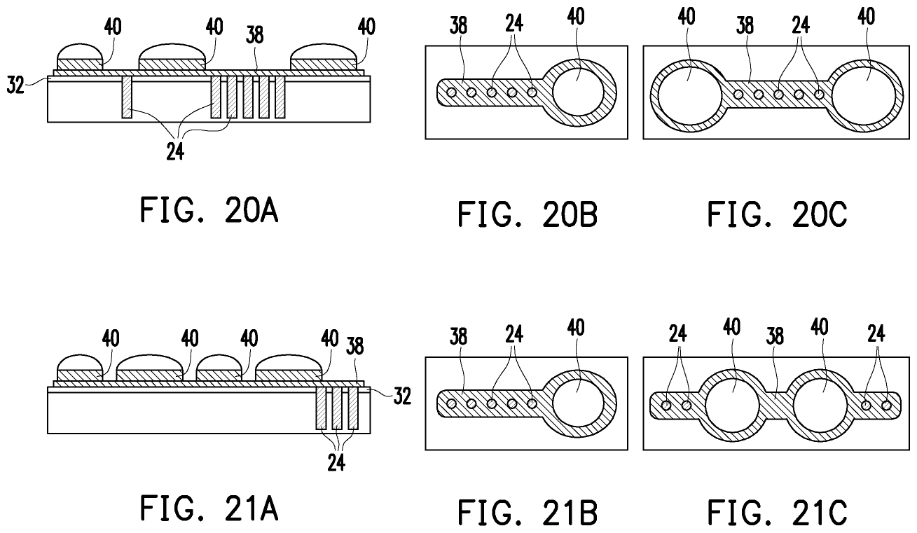

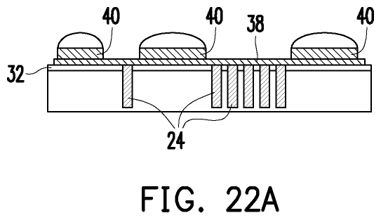

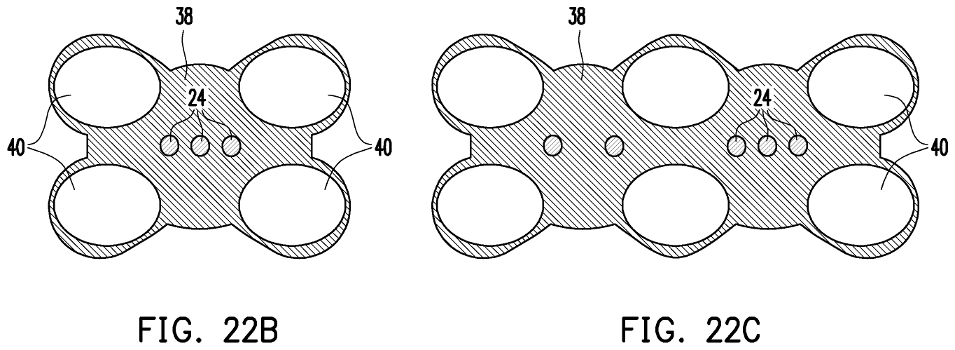

FIGS. 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, and 22C illustrate the cross-sectional views and bottom views of TSVs 24, backside RDLs 38 and metal bumps 40 in accordance with various embodiments. Some reference numbers are marked to show the corresponding features, which features may be found from FIGS. 9 and 10. The Figures followed by letter B or C are the bottom views of the corresponding figures that having the same number, but are followed by letter A. The figures whose numbers include letter B and the Figures whose numbers include letter C illustrate different embodiments.

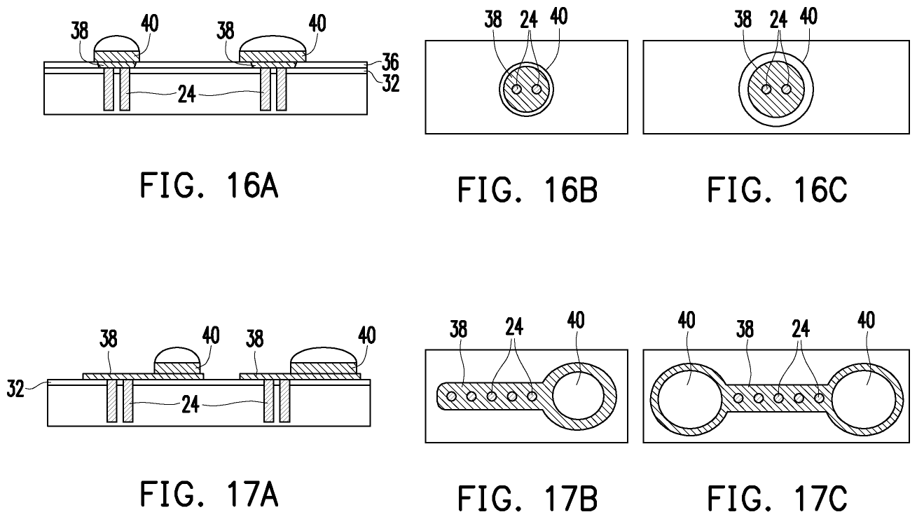

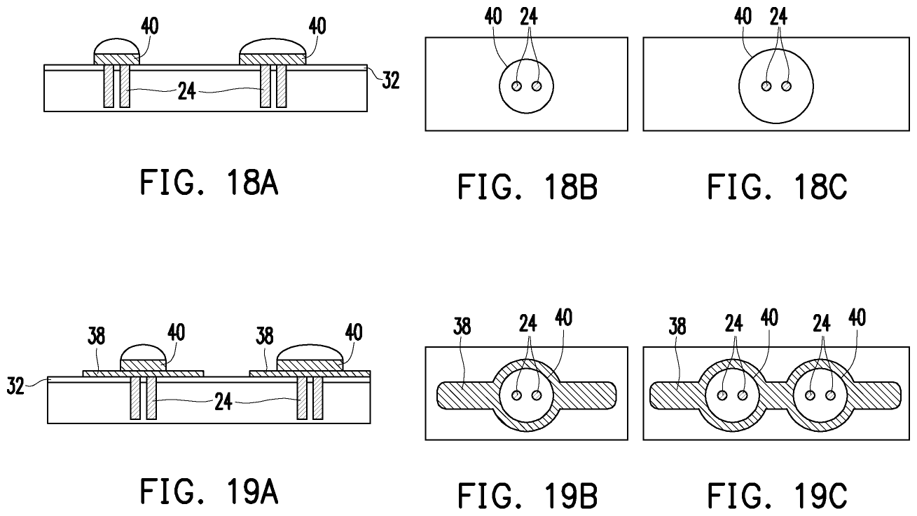

As shown in these Figures, backside RDLs 38 may include pad portions that are wide and trace portions that are elongated and narrower than the pad portions. The metal bumps 40 may be directly over TSVs 24, as shown in FIGS. 18A, 18B, and 18C. The metal bumps 40 may be vertically offset from TSVs 24, as shown in remaining ones of these figures. In accordance with some embodiments, TSVs 24 may be directly under the pad portions of backside RDLs 38, for example, as shown in FIGS. 16A, 16B, and 16C and some other Figures. In accordance with alternative embodiments, TSVs 24 may be directly under the elongated trace portions of backside RDLs 38, for example, as shown in FIGS. 13A, 13B and 13C and some other Figures.

It is also appreciated that although the metal pads underlying TSVs 24 are not shown, each of the TSVs 24 in FIGS. 13A, 13B, and 13C through 22A, 22B, and 22C may have a separate metal pad, same as the metal pads 92′ and 92″ as shown in FIG. 10, and each of the TSVs 24 may be connected to a separate integrated circuit than other TSVs 24, which integrated circuits are illustrated as integrated circuits 94′ and 94″ in FIG. 10.

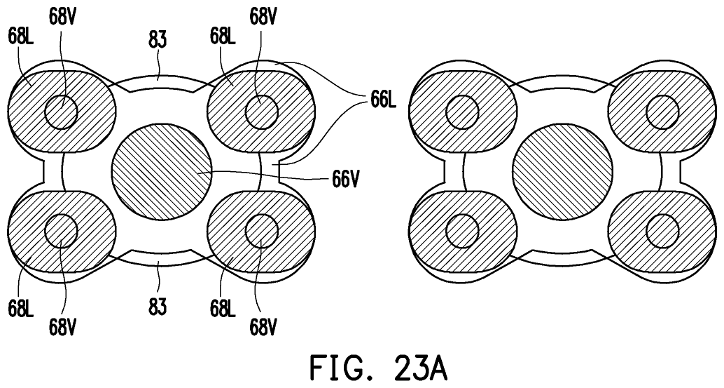

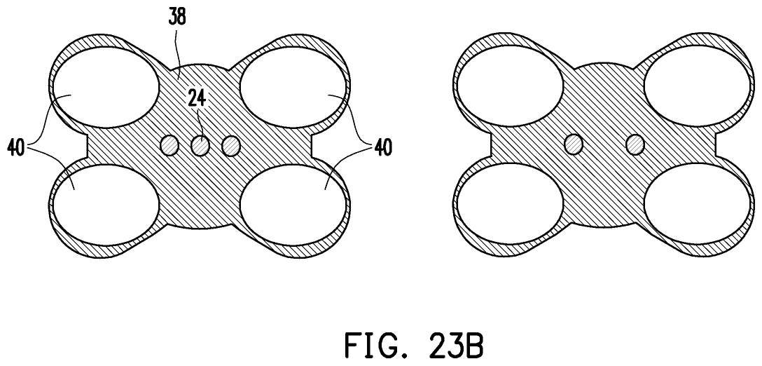

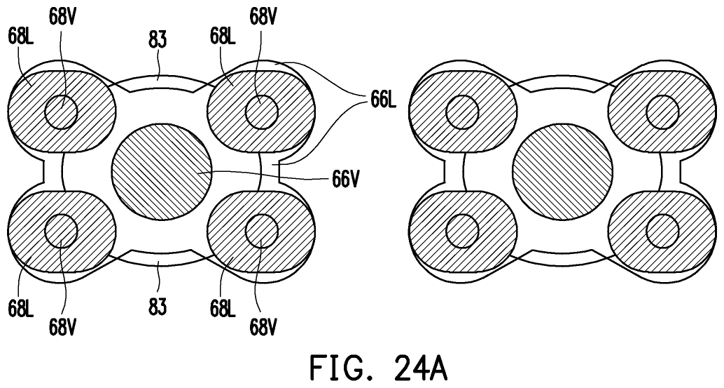

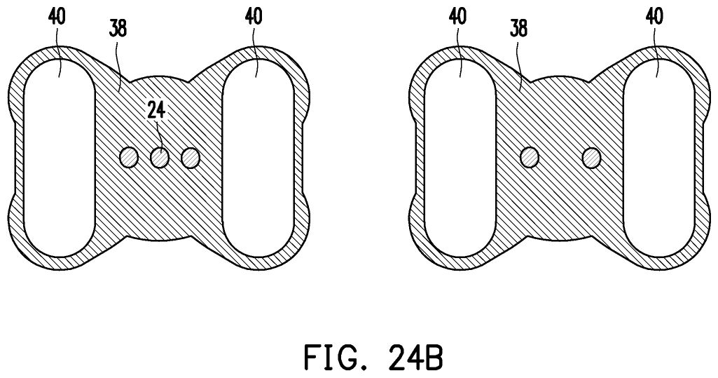

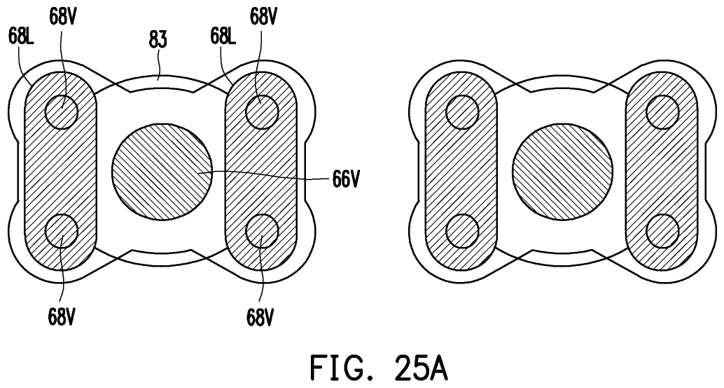

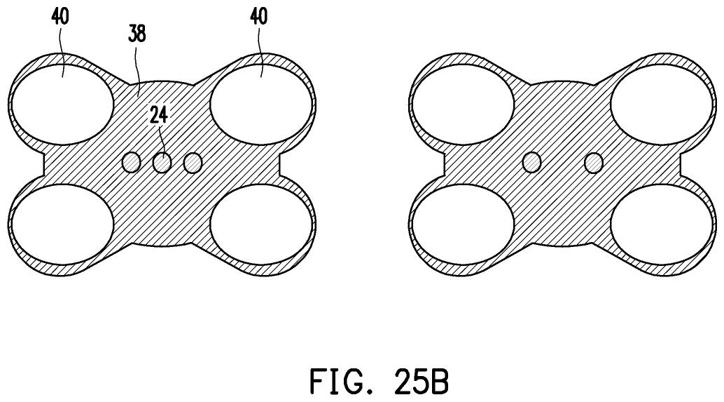

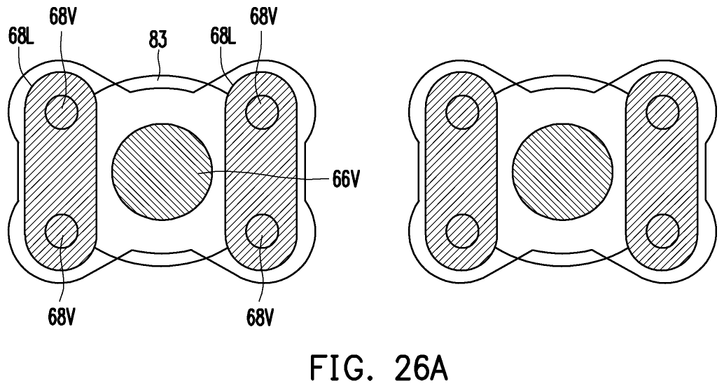

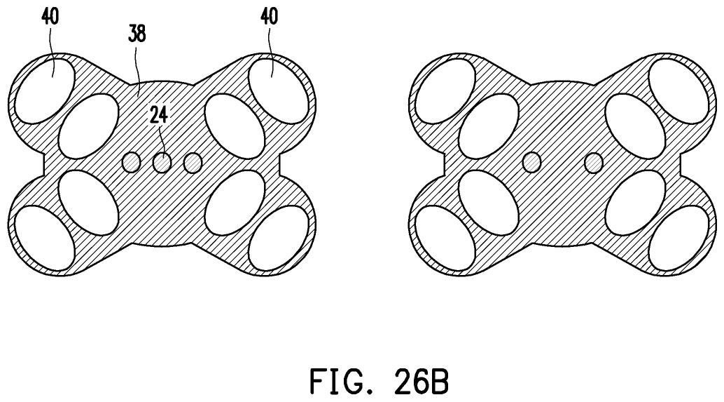

FIGS. 23A, 23B, 24A, 24B, 25A, 25B, 26A, and 26B illustrate the bottom views of the features as shown in FIG. 10 in accordance with some embodiments. These Figures illustrate the example ratios of the features that are connected to the same mRDL 66. In FIGS. 23A and 23B, the ratio of the number of metal bumps 40 to the number of RDL trace portions 68L is 4:4 (which is 1:1). In FIGS. 24A and 24B, the ratio of the number of metal bumps 40 to the number of RDL trace portions 68L is 2:4 (which is 1:2). In FIGS. 25A and 25B, the ratio of the number of metal bumps to the number of RDL trace portions 68L is 4:2 (which is 2:1). In FIGS. 26A and 26B, the ratio of the number of metal bumps to the number of RDL trace portions 68L is 8:2 (which is 4:1). It is appreciated that any other applicable ratio is also contemplated.

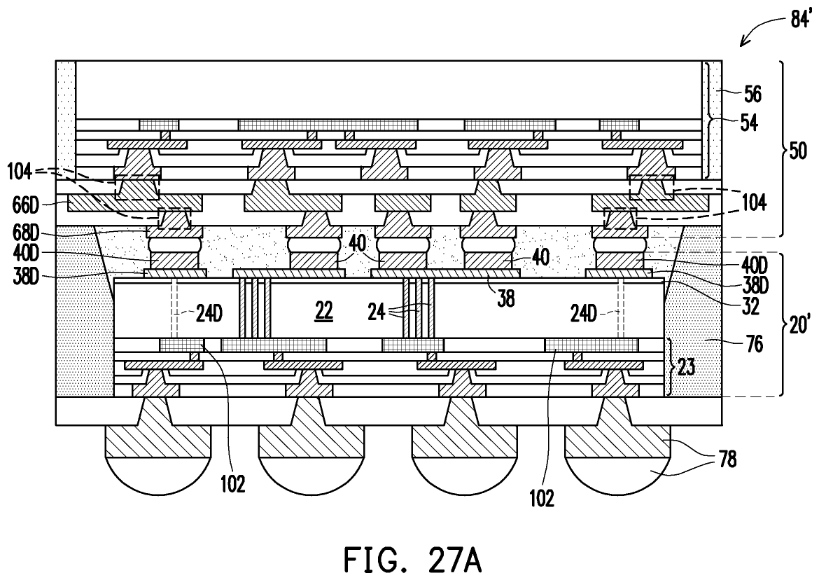

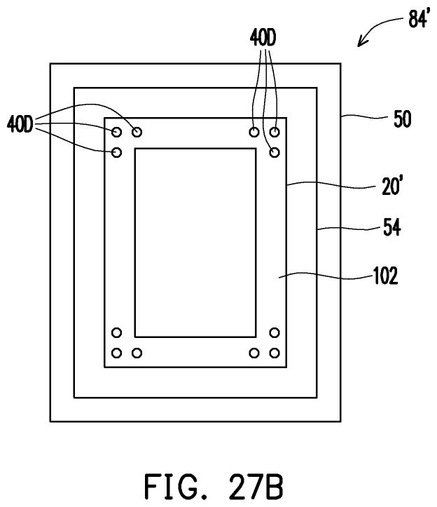

FIGS. 27A and 27B illustrate a cross-sectional view and a top view, respectively, of package 84′ in accordance with some embodiments of the present disclosure. In accordance with these embodiments, in additional to the signal integration scheme achieved through the backside RDLs 38 and mRDLs 66 (as discussed in preceding embodiments), dummy bumps 40D are formed directly over seal ring(s) 102 to improve the robustness of the bonding. It is appreciated that although not shown in detail, the following embodiments also implement the signal integration scheme as shown in FIGS. 9 and 10, and the details are not illustrated and discussed, but can be found in the discussion of the previous embodiments.

As shown in FIGS. 27A and 27B, package 84′ includes InFO package 50 and TSV die 20′ bonding to the InFO package 50. In accordance with some embodiments, signal TSVs 24 and functional circuits (such as 94′ and 94″ in FIG. 10) are formed in an inner region of TSV die 20′ encircled by seal ring 102. In subsequently discussed embodiments, letter “D” may be added to some features to indicate that these features are dummy features that do not have electrical functions. For example, the dummy features include dummy bumps 40D, dummy backside RDLs 38D, dummy UBMs 68D, dummy mRDLs 66D, dummy TSVs 24D, and the like. The dummy features may be electrically floating.

Dummy bumps 40D are formed on dummy backside RDLs 38D. Seal ring 102 is directly underlying, and is overlapped by, dummy bumps 40D and backside RDLs 38D in accordance with some embodiments. In accordance with some embodiments, the features (such as vias) in the dashed regions 104 may not be formed, so that dummy bumps 40D are electrically decoupled from device die 54.

In accordance with some embodiments, dummy TSVs 24D may be formed directly underlying and connected to dummy bumps 40D and backside RDL 38D. In accordance with alternative embodiments, dummy TSVs 24D are not formed. Accordingly, dummy TSVs 24D are shown as being dashed to indicate that dummy TSVs 24D may or may not be formed.

In accordance with some embodiments, seal ring 102 is formed in the interconnect structure 23 of the TSV die 20′. For example, each seal ring 102 may include a plurality of metal line ring, and a plurality of via rings between, and joined to, the respective overlying and underlying metal line rings. Each of the metal line rings and via rings may be a solid metal ring, and the respective seal ring 102 is also a solid metal ring. The seal ring 102 may extend into all of the low-k dielectric layers in the interconnect structure 23, and may or may not extend into inter-layer dielectric layers of TSV die 20′. The seal ring 102 is at the peripheral region of TSV die 20′, and encircles signal TSVs 24 and integrated circuits 94 (FIG. 10) therein.

FIG. 27B illustrates a top view of the package shown in FIG. 27A. The outer edges of InFO package 50, TSV die 20′, and device die 54 are illustrated. In accordance with some embodiments, InFO package 50 is larger than device die 54, which is further larger than TSV die 20′. The seal ring 102 form a ring, with a plurality of dummy bumps 40D overlapping (in the cross-sectional view) the seal ring 102. In accordance with some embodiments, dummy bumps 40D are at the corner regions of TSV die 20′ and seal ring 102.

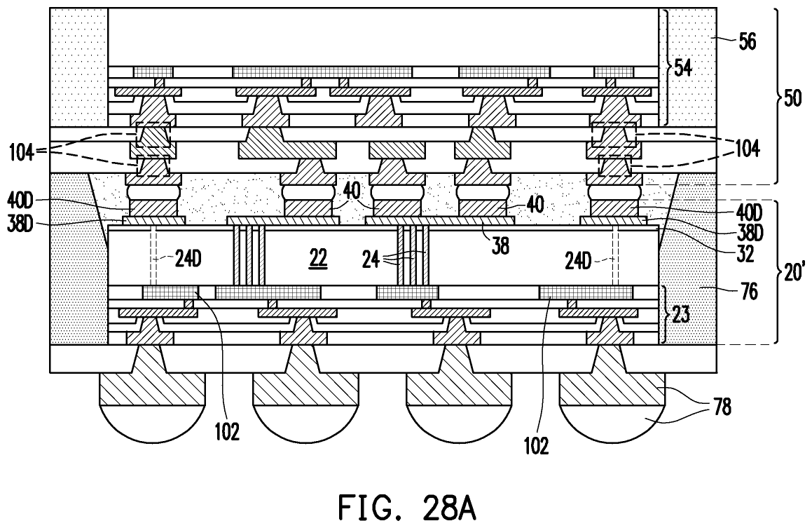

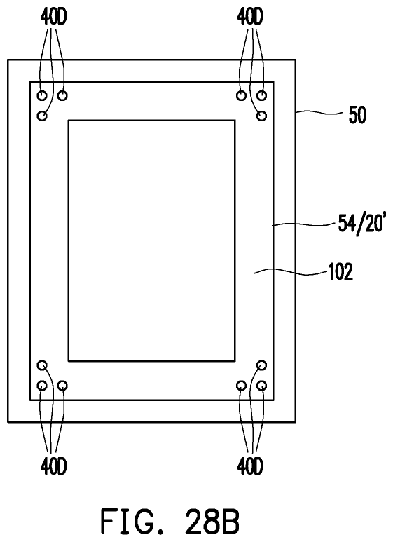

FIGS. 28A and 28B illustrate a cross-sectional view and a top view, respectively, of the package 84′ in accordance with alternative embodiments. These embodiments are similar to the embodiments shown in FIGS. 27A and 27B, except that the device die 54 and TSV die 20′ have their edges aligned. InFO package 50, on the other hand, is larger than TSV die 20′ and device die 54. Dummy bumps 40D are at the corner regions of TSV die 20′ and seal ring 102.

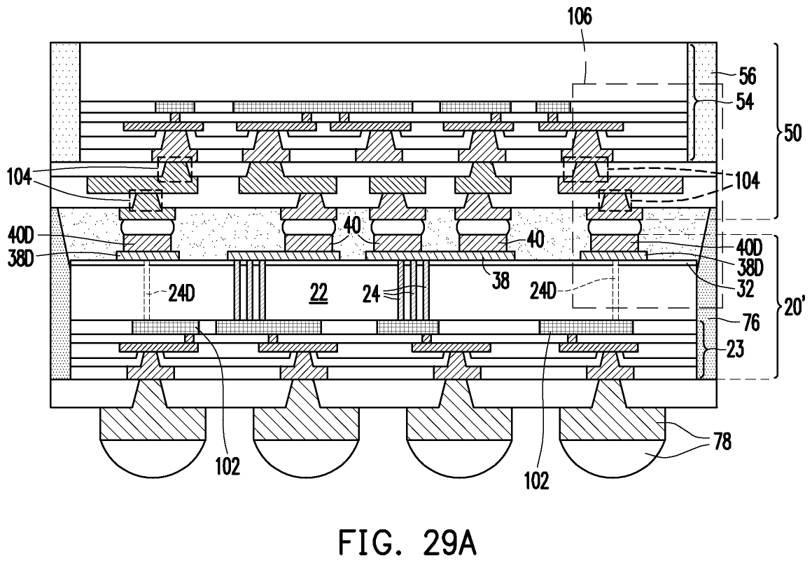

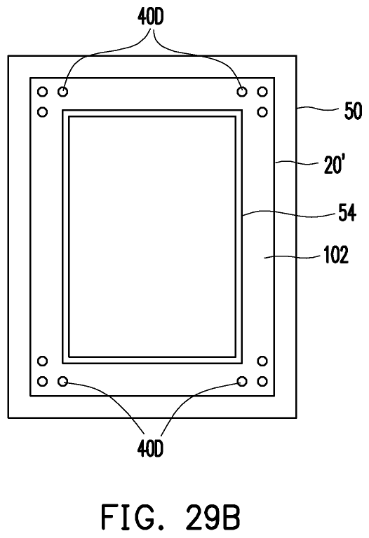

FIGS. 29A and 29B illustrate a cross-sectional view and a top view, respectively, of the package 84′ in accordance with yet alternative embodiments. These embodiments are similar to the embodiments shown in FIGS. 27A and 27B, except that InFO package 50 is larger than the TSV die 20′, which is further larger than device die 54. Dummy bumps 40D are at the corner regions of TSV die 20′ and seal ring 102.

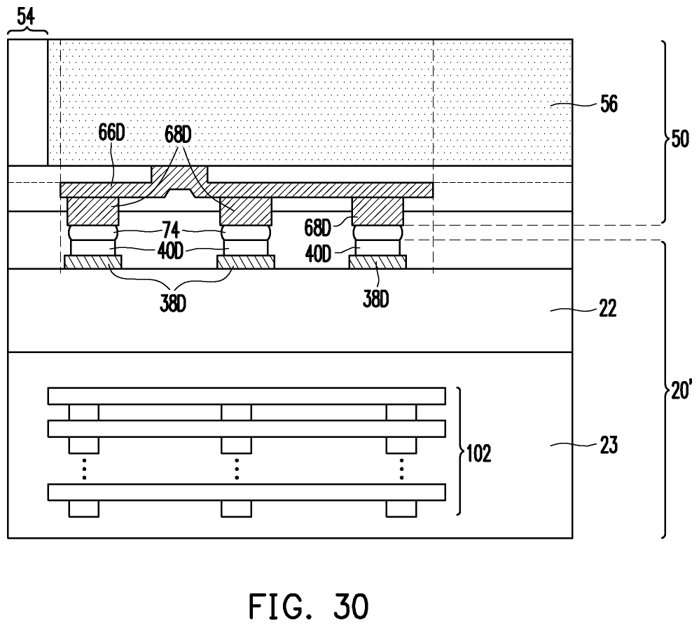

FIG. 30 illustrates a portion of the package 84′ shown in FIG. 29A in accordance with some embodiments, in which both of the InFO package 50 and TSV die 20′ are larger than device die 54. FIG. 30 illustrates the edge region 106 in FIG. 29A. In accordance with some embodiments, dummy bumps 40D, dummy UBMs 68D, and dummy RDLs 66D extend laterally beyond the right edge of device die 54, and are directly underlying gap-filling regions 56. Dummy bumps 40D overlap seal ring 102 in TSV die 20′. This further improves the bonding robustness. Dummy TSVs 24D are not illustrated (refer to FIG. 29A), while they may (or may not) exist in the structure shown in FIG. 30.

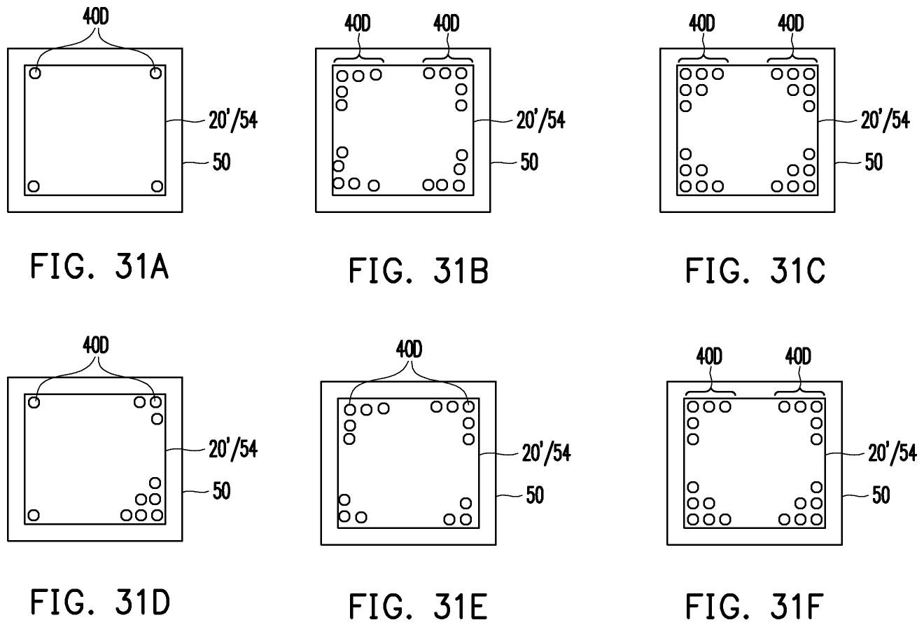

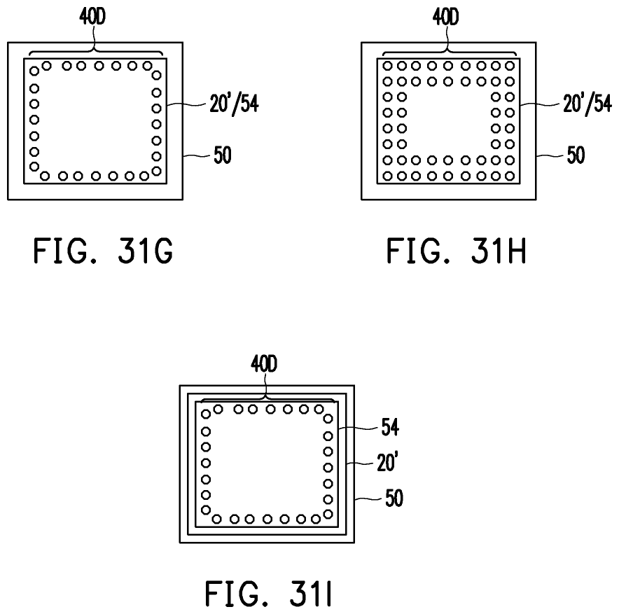

FIGS. 31A through 31E illustrate the top views of dummy bumps 40D relative to the sizes of InFO package 50, TSV die 20′, and device die 54 in accordance with some embodiments. The illustrated examples show that the TSV die 20′ have a same size as device dies 54, while both having smaller sizes than InFO package 50. In other embodiments, however, the size of each of TSV die 20′, device die 54, and InFO package 50 may be larger than, equal to, or smaller than other ones in any combination. Each of the embodiments shown in FIGS. 31A through 31E thus may be applicable to each of the embodiments shown in FIGS. 27B, 28B, and 29B.

In FIGS. 31A through 31E, seal rings 102 are not shown, while they still exist and are overlapped by dummy bumps 40D. The sizes and shapes of seal rings 102 may be the same as what are shown in FIGS. 27B, 28B, and 29B.

As shown in FIGS. 31A, 31B, and 31C, the total count of dummy bumps 40D at each corner of TSV die 20′ may be any number such as 1, 2, 3, 5, 6, or the like. The distribution of dummy bumps 40D at the corners may be symmetric as shown in FIGS. 31A, 31B, and 31C. Alternatively, dummy bumps 40D at different corners may have asymmetric arrangement relative to each other, as shown in FIGS. 31D, 31E, and 31F.

FIGS. 31G, 31H, and 31I illustrate the embodiments of dummy bumps 40D. In accordance with these embodiments, dummy bumps 40D are aligned as rings. There may be one ring formed of dummy bumps 40D, two rings formed of dummy bumps 40D, or more rings.

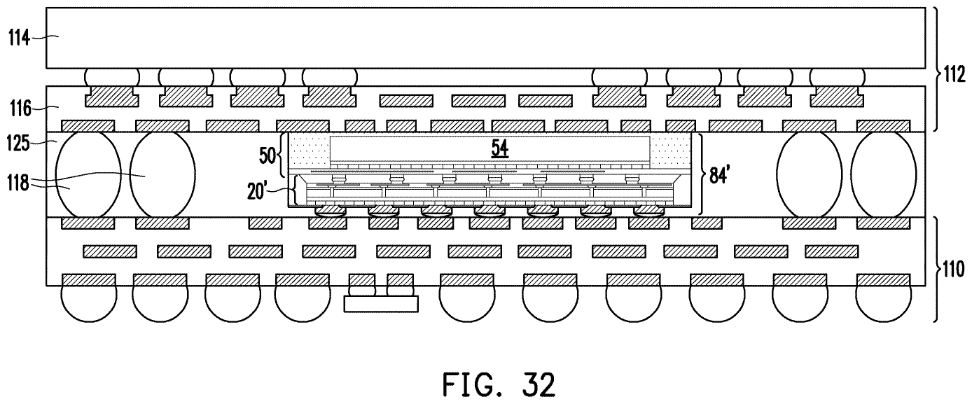

FIGS. 32, 33, and 34 illustrate some applications in which the package 84′ may be incorporated in accordance with some embodiments. Referring to FIG. 32, package 84′ is bonded on package substrate 110. Another package 112 including memory dies/package 114 bonding to package substrate 116 is further over and bonded to package substrate 110 through solder regions 118. Solder regions 118 and package 84′ are further encapsulated in encapsulant 125, which may be a molding compound.

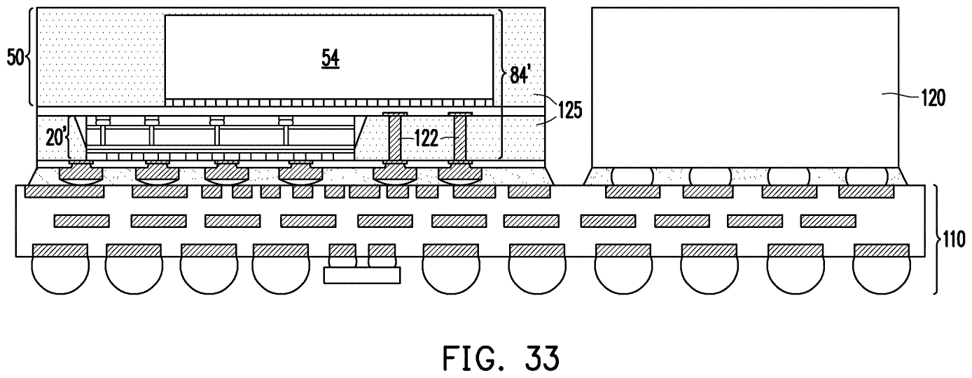

Referring to FIG. 33, package 84′ is bonded to package substrate 110, on which a multi-chip package 120 including a plurality of stacked device dies is bonded. In accordance with these embodiments, device die 54 and the corresponding InFO package 50 may be vertically offset from TSV die 20′. Through-vias 122 may be formed to directly connect InFO package 50 to package substrate 110 in accordance with some embodiments.

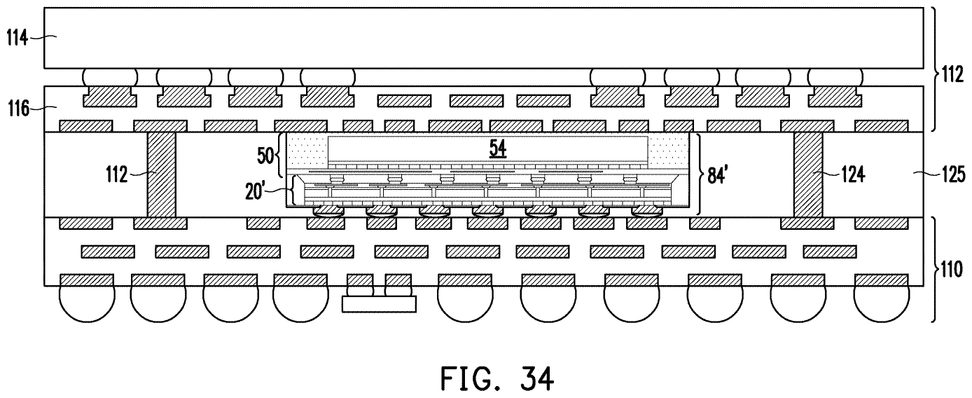

Referring to FIG. 34, package 84′ is bonded on package substrate 110. Another package 112 including memory dies/package 114 bonding to package substrate 116 is further over and bonding to package substrate 110 through through-vias 124. Through-vias 124 and package 84′ are further encapsulated in encapsulant 125, which may be a molding compound.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By using the backside RDLs of TSV dies to integrate signals, fewer metal bumps are needed because a plurality of TSVs may share the same backside RDLs and/or the overlying metal bumps. The signals may also be integrated by mRDLs to further reduce the number of RDLs. Furthermore, by forming dummy bumps directly over seal rings, the reliability of the bonding is improved.

In accordance with some embodiments of the present disclosure, a method comprises forming a die comprising forming a first through-via and a second through-via extending from a front side of a semiconductor substrate into the semiconductor substrate, wherein the first through-via and the second through-via are connected to a first integrated circuit device and a second integrated circuit device, respectively, in the die; performing a backside grinding process to reveal the first through-via and the second through-via; and forming a backside redistribution line physically joining to both of the first through-via and the second through-via.

In an embodiment, the method further comprises bonding the die to a package component, wherein the package component comprises a middle redistribution line, wherein the middle redistribution line is electrically connected to both of the backside redistribution line of the die and a third through-via penetrating through the semiconductor substrate, and wherein the third through-via is electrically connected to a third integrated circuit. In an embodiment, the package component comprises an under-bump metallurgy physically contacting a solder region, wherein a metal bump of the die is between, and physically joining to the solder region and the backside redistribution line.

In an embodiment, the first integrated circuit device and the backside redistribution line are on opposite sides of the semiconductor substrate. In an embodiment, the method further comprises, after the backside grinding process, recessing the first through-via and the second through-via, so that end portions of the first through-via and the second through-via protrude out of the semiconductor substrate; and forming a dielectric isolation layer, wherein the end portions are in the dielectric isolation layer. In an embodiment, the backside redistribution line physically contacts the dielectric isolation layer. In an embodiment, the backside redistribution line comprises a metal pad and an elongated metal line connecting to the metal pad, and the metal pad physically contacts both of the first through-via and the second through-via.

In an embodiment, the backside redistribution line comprises a metal pad and an elongated metal line connecting to the metal pad, and the elongated metal line physically contacts both of the first through-via and the second through-via. In an embodiment, the method further comprises forming a plurality of metal bumps physically contacting the backside redistribution line. In an embodiment, the method further comprises forming a plurality of solder regions contacting the plurality of metal bumps. In an embodiment, the method further comprises forming a seal ring in the die; and forming a dummy bump overlapping the seal ring. In an embodiment, the method further comprises bonding a solder region contacting the dummy bump.

In accordance with some embodiments of the present disclosure, a structure comprises a die comprising a semiconductor substrate; a first integrated circuit device and a second integrated circuit device on a front side of the semiconductor substrate; a first through-via and a second through-via penetrating through the semiconductor substrate, wherein the first through-via and the second through-via are connected to the first integrated circuit device and the second integrated circuit device, respectively; and a first backside redistribution line on a backside of the semiconductor substrate, wherein the first backside redistribution line physically contacts both of the first through-via and the second through-via.

In an embodiment, the structure further comprises a second backside redistribution line on the backside of the semiconductor substrate; a first metal bump and a second metal bump contacting the first backside redistribution line and the second backside redistribution line, respectively; and a first solder region and a second solder region contacting the first metal bump and the second metal bump, respectively. In an embodiment, the structure further comprises a first under-bump metallurgy and a second under-bump metallurgy contacting the first solder region and the second solder region, respectively; and a middle redistribution line contacting both of the first under-bump metallurgy and the second under-bump metallurgy.

In an embodiment, the structure further comprises a first metal pad and a second metal pad on the front side of the semiconductor substrate and contacting the first through-via and the second through-via, respectively. In an embodiment, the structure further comprises a first electrical path and a second electrical path electrically connecting the first metal pad and the second metal pad to the first integrated circuit device and the second integrated circuit device, respectively.

In accordance with some embodiments of the present disclosure, a structure comprises a die comprising a semiconductor substrate; a first integrated circuit and a second integrated circuit at a front side of the semiconductor substrate; a dielectric isolation layer contacting a back surface of the semiconductor substrate; and a backside redistribution line contacting the dielectric isolation layer, wherein the backside redistribution line electrically connects the first integrated circuit to the second integrated circuit. In an embodiment, the structure further comprises a first metal pad and a second metal pad on the front side of the semiconductor substrate and electrically connected to the first integrated circuit and the second integrated circuit, respectively; and a first through-via and a second through-via physically joined to the first metal pad and the second metal pad, respectively, wherein the first through-via and the second through-via penetrate through the semiconductor substrate, and are electrically connected to the first integrated circuit and the second integrated circuit through the first metal pad and the second metal pad, respectively. In an embodiment, the structure further comprises a metal bump on the backside redistribution line; a solder region on the metal bump; and a package joined to the solder region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A structure comprising:
a die comprising:
a semiconductor substrate;
an interconnect structure on a first side of the semiconductor substrate, the interconnect structure comprising a first metal pad and a second metal pad;
a first through-via and a second through-via penetrating through the semiconductor substrate, wherein the first through-via and the second through-via are joined to the first metal pad and the second metal pad, respectively; and
a first redistribution line on a second side of the semiconductor substrate, wherein the first redistribution line physically contacts the first through-via and the second through-via.

2. The structure of claim 1 further comprising a first integrated circuit device and a second integrated circuit device on a front side of the semiconductor substrate, wherein the first integrated circuit device and the second integrated circuit device are electrically connected to the first metal pad and the second metal pad, respectively.

3. The structure of claim 2, wherein the first integrated circuit device and the second integrated circuit device are physically separated devices.

4. The structure of claim 2 further comprising:
a first electrical path and a second electrical path electrically in the interconnect structure and connecting the first metal pad and the second metal pad to the first integrated circuit device and the second integrated circuit device, respectively.

5. The structure of claim 1 further comprising:
a second redistribution line on the second side of the semiconductor substrate; and
a first metal bump and a second metal bump contacting the first redistribution line and the second redistribution line, respectively.

6. The structure of claim 5 further comprising:
a first solder region and a second solder region contacting the first metal bump and the second metal bump, respectively.

7. The structure of claim 6 further comprising:
a first under-bump metallurgy and a second under-bump metallurgy contacting the first solder region and the second solder region, respectively; and
a middle redistribution line contacting both of the first under-bump metallurgy and the second under-bump metallurgy.

8. The structure of claim 1, wherein the first side is a front side of the semiconductor substrate, and the second side is a backside of the semiconductor substrate.

9. A structure comprising:
a die comprising:
a semiconductor substrate;
a first integrated circuit and a second integrated circuit on a side of the semiconductor substrate;
a dielectric isolation layer contacting a surface of the semiconductor substrate;
a first through-via and a second through-via in the semiconductor substrate and the dielectric isolation layer; and
a redistribution line contacting the dielectric isolation layer, wherein the redistribution line is electrically connected to the first integrated circuit and the second integrated circuit.

10. The structure of claim 9 further comprising:
a first metal pad and a second metal pad connected to the first integrated circuit and the second integrated circuit, wherein the first through-via and the second through-via are physically joined to the first metal pad and the second metal pad, respectively.

11. The structure of claim 10, wherein the first metal pad and the second metal pad are physically separated from each other.

12. The structure of claim 9 further comprising:
a third through-via in the semiconductor substrate;
a first solder region and a second solder region connected to the first through-via and the third through-via, respectively; and
a middle redistribution line connected to the first solder region and the second solder region, wherein the middle redistribution line and the redistribution line are on opposite sides of the first solder region.

13. The structure of claim 9, wherein the first integrated circuit and the second integrated circuit are physically separated circuits.

14. The structure of claim 9 further comprising a front-side interconnect structure electrically connecting the first through-via and the second through-via to the first integrated circuit and the second integrated circuit, respectively.

15. The structure of claim 9, wherein the dielectric isolation layer contacts a back surface of the semiconductor substrate.

16. The structure of claim 9 further comprising:
a metal bump on the redistribution line;
a solder region on the metal bump; and
a package joined to the solder region.

17. A structure comprising:
a first device die comprising:
a semiconductor substrate;
a first through-via, a second through-via, a third through-via, and a fourth through-via in the semiconductor substrate;
a first redistribution line over and joined to the first through-via and the second through-via;
a second redistribution line over and joined to the third through-via and the fourth through-via; and
a first solder region and a second solder region over and electrically connected to the first redistribution line and the second redistribution line, respectively; and
a redistribution structure comprising a redistribution line, wherein the redistribution line is over and electrically connected to the first solder region and the second solder region, respectively.

18. The structure of claim 17 further comprising a second device die over and electrically connected to the redistribution line.

19. The structure of claim 18 further comprising a gap-filling region comprising portions contacting opposite sidewalls of the second device die, wherein the gap-filling region is over and contacting the redistribution structure.

20. The structure of claim 17, wherein the first device die further comprises:
a first integrated circuit structure, a second integrated circuit structure, a third integrated circuit structure, and a fourth integrated circuit structure electrically connected to the first through-via, the second through-via, the third through-via, and the fourth through-via, respectively.
